(19) United States
(12) Patent Application Publication
(10) Pub. No.: US 2018/0188302 A1
(43) Pub. Date: Jul. 5, 2018

(54) DETERMINING AN ALTERNATING CURRENT (AC) CHARACTERISTIC FROM A WAVEFORM

(71) Applicant: Hewlett Packard Enterprise Development LP, Houston, TX (US)

(72) Inventors: Daniel Humphrey, Tomball, TX (US); Michael Delany, Houston, TX (US); Mohamed Amin Bernat, Cypress, TX (US)

(21) Appl. No.: 15/737,612

(22) PCT Filed: Jun. 26, 2015
(86) PCT No.: PCT/US2015/037958

§ 371 Date: Dec. 18, 2017

(51) Int. Cl. G01R 23/02; G01R 19/00; G01R 19/04; G01R 19/165

(52) U.S. Cl. CPC G01R 23/02; G01R 19/165; G01R 19/04; G01R 19/0084

(57) ABSTRACT

Examples herein disclose a system comprising a comparator circuit and a controller. The comparator circuit generates a waveform of an input source. The controller measures a period of time associated with the waveform and determines an alternating current (AC) characteristic of the input source based on the measured period of time.

### BACKGROUND

Power systems are networks of various components to supply, transmit, and use electrical power. In the power system, a controller coordinates the various components to supply the electrical power to a load. The controller transmits commands to the various components to respond to conditions within the power system.

### BRIEF DESCRIPTION OF THE DRAWINGS

In the accompanying drawings, like numerals refer to like components or blocks. The following detailed description references the drawings, wherein:

FIG. 1 illustrates an example system in accordance with the present disclosure:

FIGS. 2A-2B illustrates an example circuit to generate a waveform in accordance with the present disclosure;

FIG. 3 illustrates an example flow diagram to determine a frequency based on a measured period of time from a waveform in accordance with the present disclosure;

FIG. 4 illustrates an example flow diagram to respond to a verification of a frequency is within a range of values in accordance with the present disclosure;

FIG. 5 illustrates a block diagram of an example computing device with a processing resource to execute instructions in a machine-readable storage medium for determining a characteristic based on a measured period of time as in accordance with the present disclosure; and

FIG. 6 illustrates a block diagram of an example computing device with a processing resource to execute instructions in a machine-readable storage medium for determining if a characteristic is within a range of values and responding as in accordance with the present disclosure.

### DETAILED DESCRIPTION

Power systems experience various conditions which may affect a capability of supplying adequate power to a load. The various conditions may include, by way of example, whether a power supply is operating within its specification limits. As such, there are various mechanisms to detect whether the power supply is within these specification limits. One mechanism includes using a flyback converter to convert the input from the power supply; however flyback converters may take longer to detect changes to the specification limits of the power supply. Another mechanism uses an analog optocoupler to transfer electrical signals between the power supply and the load by using light; however, optocouplers can be costly and are temperature sensitive which can compromise the reliability of detecting changes to the power supply.

To address these issues, examples disclose a system to provide a reliable, inexpensive alternative to measure a specification limit of an input source. The system comprises a comparator circuit to generate a waveform representative of the input source. The system utilizes a controller to measure a period of time in the waveform. Upon measuring the period of time in the waveform, the controller uses this measurement to determine an alternating current (AC) characteristic value of the input source. The AC characteristic value may include, by way of example, a frequency value of the voltage or an amplitude value of the voltage as provided by the input source. Determining a value of the AC characteristic, the controller is used to verify the operating condition of the input source to ensure it is operating within the specification limits.

Additionally, using the waveform generation to infer the AC characteristic value provides a reliable mechanism to determine whether the input source is operating within the specification limits. Using the waveform to determine the AC characteristic reduces the cost of the system.

In another example, the power system provides a proactive approach if the AC characteristics are outside of the specification limits. In this example, upon determining the AC characteristic value of the input source is outside of the specification limits, the controller transmits a signal to a power conditioning module to compensate the input source to ensure the system is operating within the specification limits.

In the ensuing discussion, reference may be made to electrical power systems generating waveforms. It is to be understood, however, that various components discussed below can also be used in conjunction with optical components and systems.

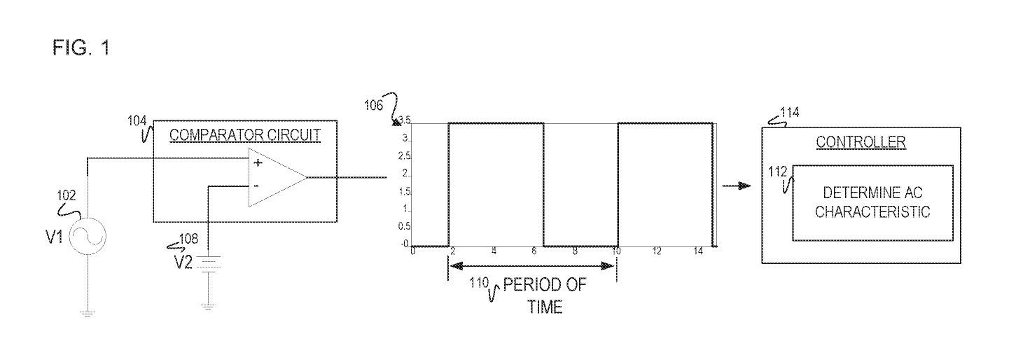

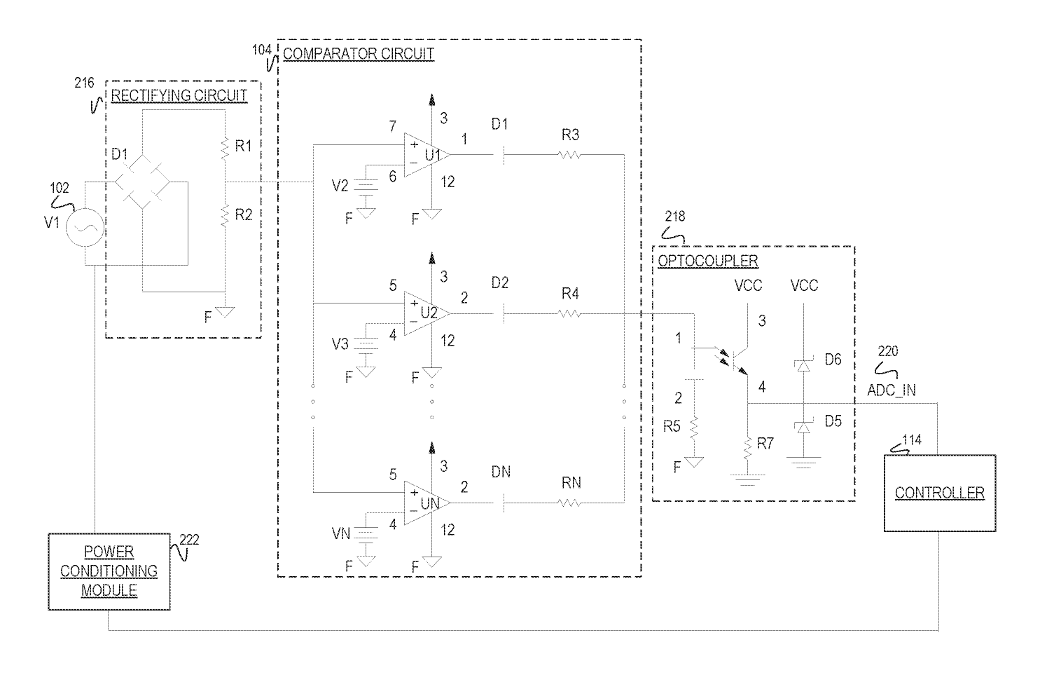

Referring now to the figures, FIG. 1 illustrates an example system for inferring an AC characteristic from a waveform. The system includes an input source 102 which provides a voltage signal to a comparator circuit 104. The comparator circuit 104 receives the voltage signal and produces another voltage signal observed in a waveform 106. The comparator circuit 104 uses the voltage signal produced by the input source 102 and compares to a known voltage 108 to produce the waveform 106. This waveform 106 is considered a pseudo-digitized version of the voltage signal from the input source. In other implementations, the waveform uses a comparison between the voltage signal provided to the comparator circuit 104 and the voltage signal produced by the comparator circuit 104. This may be observed in the next figure.

A controller 114 uses the waveform 106 to measure a period of time 10 associated with the voltage signal produced by the comparator circuit 104. Upon measuring the period of time 110, the controller 114 determines an alternating current (AC) characteristic of the input source 102 at module 112. The system in FIG. 1 represents a sensing system in which one or more input source(s) 102 provide power to a load. In this system, the controller 114 coordinates electrical components, such as the input source 102 and comparator circuit 104 to supply electrical power to the load. Additionally, the system uses the waveform 106 in which to infer the AC characteristic(s) of the input source 102. In this manner, the system comprises components 102, 104, 114 in which to decode information from the voltage signal in waveform 106 to determine the AC characteristic(s). Implementations of the system include, by way of example, a sensing circuit, power circuit, embedded system, power supply system, computing system, distributed power system, or other type of power system. Although FIG. 1 illustrates the electrical component in the power system comprising the input source 102, comparator circuit 104, and controller 114, implementations should not be limited as the power system may also include a power conversion module.

The input source 102 is a voltage source which provides AC to the comparator circuit 104 such that the input source 102 develops the voltage signal on the waveform 106. As such, implementations of the input source 102 includes a power supply, power feed, power source, generator, power circuit, energy storage, or other type of voltage source. In one implementation, the input source 102 comprises a utility line from a power supply (not illustrated).

The comparator circuit 104 compares the voltage supplied from the input source 102 to the known voltage 108 to generate a pseudo-digitized voltage signal (indicated with the solid line) on the waveform 106. The comparator circuit 104 compares the input source 102 voltage signal to the known voltage 108, such that when the voltage signal of the input source 102 exceeds the known voltage 108 creates a rising edge in the waveform 106. When the voltage signal of the input source 102 is below the known voltage 108, this creates a falling edge in the waveform 106. The known voltage 108 is an amount of voltage which is pre-defined in which to gauge the voltage signal of the input source 102. Although FIG. 1 illustrates the comparator circuit 104 with a single comparator, implementations should not be limited as the comparator circuit 104 may include additional comparators.

The waveform 106 includes the voltage signal representative of the pseudo-digitized signal produced as output by the comparator circuit 104. In another implementation, the waveform 106 includes an additional voltage signal from the input source 102 as observed in a later figure. From the waveform 106, the controller 114 measures a period of time 110. The period of time 110 represents an amount of time between voltage points on the waveform 106. For example, the period of time 110 may represent amount of time between the rising edges on the voltage signal produced by the comparator circuit 104. The period of time 110 is used by the controller 114 to determine an AC characteristic of the input source 102 at module 112. In this manner, the waveform 106 is a reconstruction of the voltage signal in which to infer an AC characteristic of the input source 102 at controller 114. Examples of such AC characteristics include frequency value and/or amplitude of the voltage produced by the input source 102. These AC characteristics are discussed in detail in a later figure.

The controller 114 obtains the waveform 106 to measure the period of time 110. Upon measuring the period of time 110, the controller 114 proceeds to determine the AC characteristic of the input source 102 at module 112. The controller 114 is an electronic device which may start and stop a timer upon observing various points in the waveform 106. The timer is able to measure the period of time 110 between the various points on the waveform 106. As such, implementations of the controller 114 include by way of example, a microcontroller, embedded controller, circuit logic, processing device, microchip, chipset, electronic circuit, microprocessor, semiconductor, central processing unit (CPU), application-specific integrated circuit (ASIC), or other type of electronic device capable of measuring the period of time 110 from the waveform 106.

At module 112, the controller 114 determines the AC characteristic of the input source 102 based on the measured period of time 110. In one implementation, the measured period of time 110 is used to determine a frequency value of the input source 102. Based on this frequency value, the controller 114 may determine whether the input source 102 is within operational or specification limits. This is explained in detail in connection with the next figure. The module 112 may include, by way of example, instructions (e.g., stored on a machine-readable medium) that, when executed (e.g., by the controller 114) implement the functionality of module 112. Alternatively, or in addition, the module 112 may include electronic circuitry (i.e., hardware) that implements the functionality of module 112.

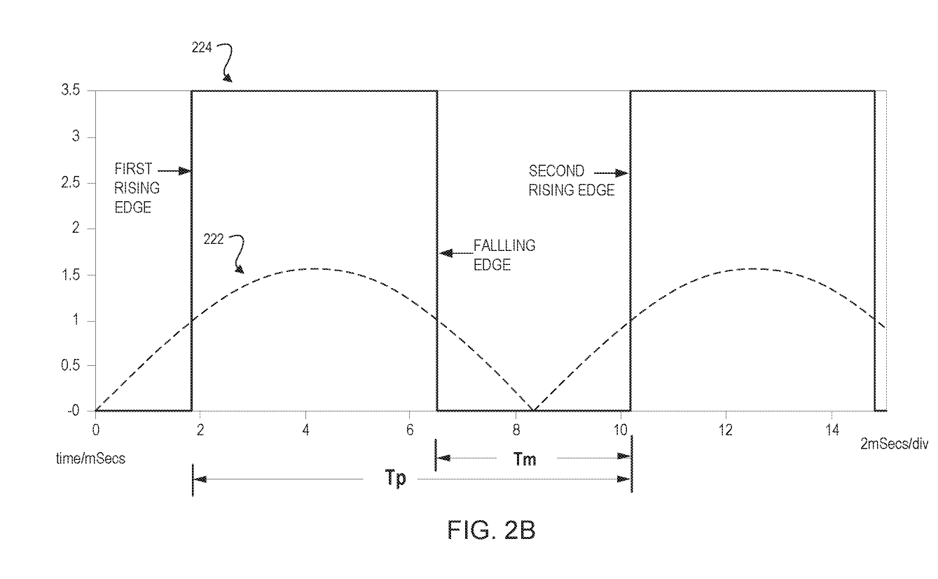

FIGS. 2A-2B illustrate an example circuit to generate an example waveform with the present disclosure. The circuit diagram and the waveform represent various components and output that may be utilized in connection with the various flowcharts and processes in later figures. Although FIGS. 2A-2B illustrate specific components, it is not intended to be so limited. Rather, it is contemplated the various components may include other equivalent components to accomplish the present disclosure.

FIG. 2A illustrates the circuit diagram to generate the waveform as in FIG. 2B. An input source 102 supplies an alternating current (AC) signal to a rectifying circuit 216. The rectifying circuit 216 rectifies the AC signal from the input source 102 and provides a voltage scaled down to a smaller amount of rectified voltage. This rectified voltage is provided to a comparator circuit 104. The comparator circuit 104 takes the rectified voltage and compares the rectified voltage to a known voltage 108 at each comparator (U1, U2, UN). The comparator circuit 104 outputs a pseudo-digitized version voltage which is passed through to an optocoupler circuit 218 and in turn to a controller 114.

The rectifying circuit 216 comprises a voltage bridge DI and a voltage divider (R1 and R2) that rectifies the voltage form the input source 102. In another implementation, the rectifying circuit 216 may include converting the AC voltage from the input source 102 to a DC voltage.

The comparator circuit 104 takes the rectified voltage from the rectifying circuit 216 and compares the rectified voltage to a known voltage (V2, V3, VN) at each of the comparators (U1, U2, UN). Comparing the rectified voltage to known voltages produces the pseudo-digitized voltage observed at label 220 (ADC_IN). Although FIG. 2A represents the comparator circuit 104 with multiple comparators (U1, U2, UN) this was done for illustration purposes. For example, the comparator circuit 104 may include a single comparator to produce the pseudo-digitized voltage 224 observed in FIG. 2B.

The optocoupler 218 provides safety isolation between the comparator circuit 104 and the controller 114 and reduce noise from the waveform provided at ADC_IN 220 to the controller 114. The optocoupler 218 comprises a photocoupler and a photo transistor (D5, D6).

FIG. 2B represents the waveform achieved as output from the circuit diagram as in FIG. 2A. The waveform includes a comparison between the voltage 222 and pseudo-digitized voltage 220. The voltage 222 on the waveform is the voltage provided to the comparator circuit 104. The pseudo-digitized voltage 220 is the voltage representation produced as output at label 220 (ADC_IN) from the comparator circuit 104. Although the pseudo-digitized voltage 220 represents a voltage from a single comparator, implementations should not be limited. For example, each additional comparator that is activated will correspond to an increase in voltage output at label 220 (ADC_IN). Likewise, when there is a deactivation of a comparator, this will cause a decrease in voltage output at label 220 (ADC_IN).

From this waveform, the controller 114 can determine various AC characteristics of the input source. The various AC characteristics are used to gauge whether the input source is operating within a range of operational limits. In this implementation, the controller measures a period of time (Tp) between a first and a second rising edge. The rising edges of the pseudo-digitized voltage 224 represents the situation when the 222 provided by the input source 102 to the comparator circuit 104 is larger than a known voltage at a comparator. When the first rising edge of the voltage 224 is detected, a timer starts counting until reaching the second rising edge. This measures the amount of time between the rising edges and used to calculate a frequency value of the input source. The controller may use the following equation (1) to determine the frequency value.

$$Frequency value = \frac{1}{2 * Tp} \qquad Equation ( 1 )$$

Upon obtaining the frequency value, the controller may proceed to determine an amplitude of the voltage provided by the input source. In this implementation, the controller measures the amount of time (Tm) between a falling edge and rising edge. This amount of time (Tm) and the frequency value is used to calculate the amplitude. The controller may use the following equation (2) to determine the amplitude.

$$Amplitude = Abs \vert \frac{Vknown}{sin ( 2 {π}^{*} frequency {value}^{*} ( Tm \text{/} 2 )} \vert \qquad Equation ( 2 )$$

The controller 114 uses the values from the calculated frequency and/or amplitude to determine if the input source 102 is operating within the specification limits. If the frequency and/or amplitude value are outside of the specification limits, the controller 114 transmits a signal to the power conditioning module 222. The power conditioning module 222 is a device intended to improve the quality of power delivered to the load. For example, the power condition module 222 may compensate the input source 102 to ensure the input source 102 is delivering a load with a frequency value within the specification limits. Implementations of the power conditioning module 222 include, by way of example, a power factor correcting device, a voltage regulator, power regulator, etc.

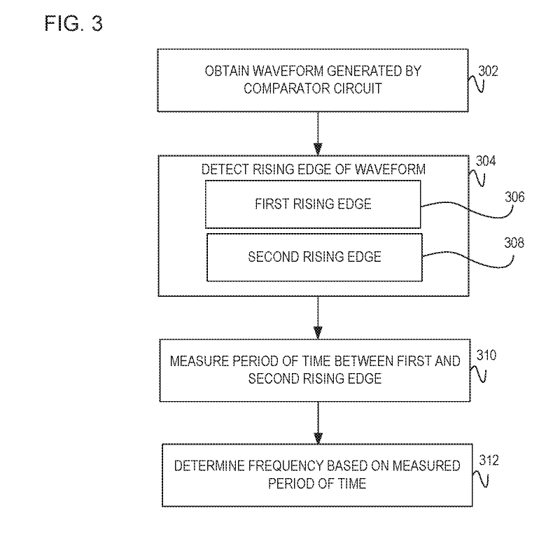

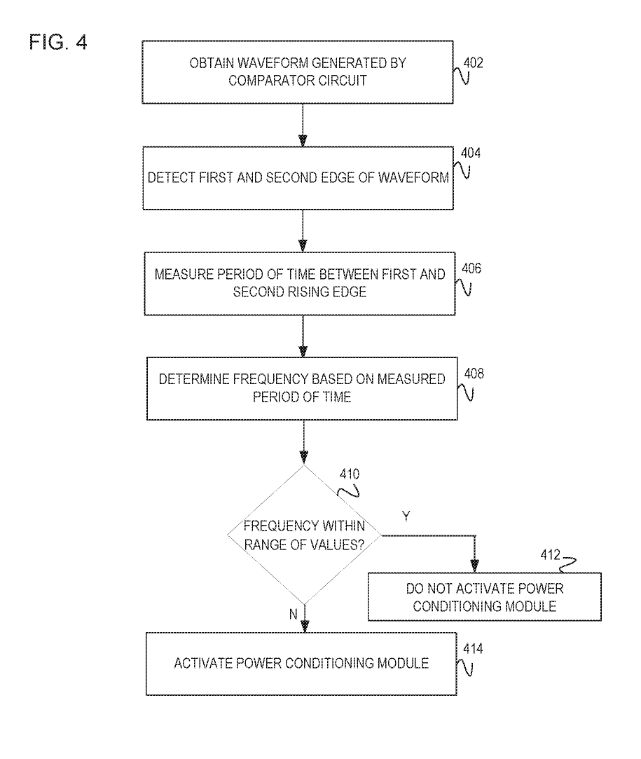

Referring now to FIGS. 3 and 4, flowcharts are illustrated in accordance with various examples of the present disclosure. The flowcharts represent processes that may be utilized in conjunction with various systems and devices as discussed with reference to the preceding figures. While illustrated in a particular order, the flowcharts are not intended to be so limited. Rather, it is expressly contemplated that various processes may occur in different orders and/or simultaneously with other processes than those illustrated.

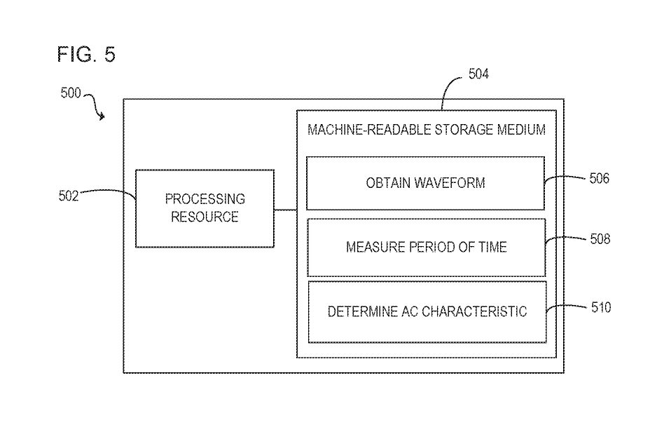

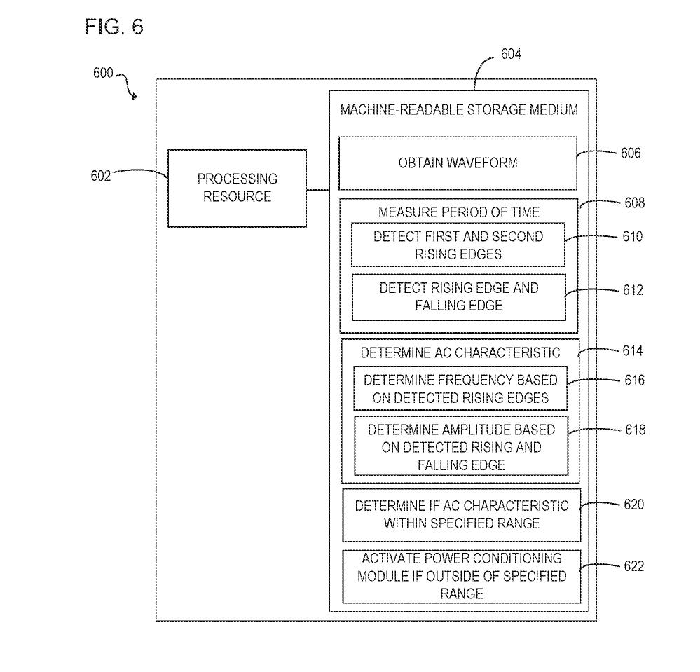

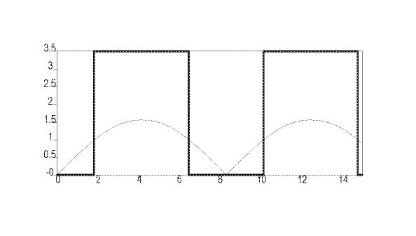

FIG. 3 is a flowchart of an example method, executable by a controller, to determine a frequency value of an input source based on a measured period of time from a waveform. The waveform represents a reconstruction of a voltage produced by a comparator circuit by comparing a voltage signal of the input source against a known voltage. This waveform may be used to identify various characteristics of the input source including a frequency of the voltage, amplitude of the voltage, etc. In discussing FIG. 3, references may be made to the components in FIGS. 1-2B to provide contextual examples. In one implementation, the controller 114 as in FIG. 1 executes operations 302-312 to determine a frequency value from a measured period of time. Although FIG. 3 is described as implemented by the controller, it may be executed on other suitable components. For example, FIG. 3 may be implemented in the form of executable instructions on a machine-readable storage medium 504 and 604 as in FIGS. 5-6.

At operation 302, the controller obtains the waveform from the comparator circuit. The input source provides AC power to the comparator circuit for generation of the waveform. Upon receiving the power from the input source, the comparator circuit performs a digitization to the AC power to produce the waveform. Obtaining the waveform, the controller proceeds to detect various rising edges of the waveform.

At operations 304-308, the controller detects the rising edges of the waveform generated by the comparator circuit at operation 302. The waveform represents a voltage signal produced from the comparator circuit. The comparator circuit uses a voltage signal from the input source and compares the input source voltage signal to a known voltage. This produces a digitized version of the input source voltage. Thus, when the voltage from the input source exceeds the known voltage, this creates the rising edge in the waveform. The controller detects each time at least two rising edges are created. The first rising edge represents an uptick in the voltage of the input source. The first rising edge may level off and include a falling edge prior to the next rising edge (e.g., second rising edge). The first and the second rising edges are those points of voltage in consecutive time. For example, the rising edges may be located consecutively next to each other on the time continuum of the waveform. In one implementation, upon the controller detecting the first rising edge, a timer is cleared to count the amount of time until the next rising edge. Upon detecting the next rising edge (i.e., the second rising edge), the controller may clear a time to detect a falling edge associated with the rising edges.

At operation 310, upon detecting the set of the rising edges at operations 304-308, the controller measures the period of time. The measured period of time represents the amount of time between when the first rising edge is detect and the second rising edge. This measurement of time is used to compute a frequency of the input source supplying the voltage.

At operation 312, the controller determines the frequency based on the measured period of time. The frequency is calculated as a ratio of 1/(2*measured period of time). Calculating the frequency, the controller is able to calculate other AC characteristics such as amplitude of the input source voltage. In another implementation, upon calculating the frequency, the controller uses the value of the frequency to gauge if the input source is operating within a range of values. The range of values are considered the operational or specification limits in which the input source should be operating. Thus, if the frequency value is outside of these operational limits, the controller transmits a signal to a power conditioning module. The power conditioning module may proceed to compensate the calculated frequency value to obtain a value within the operational limits. This implementation is discussed in connection with FIG. 4.

FIG. 4 is a method, executable by a controller for responding to a verification of a frequency value. The controller obtains a waveform generated from a comparator circuit and proceeds to detect a first and a second rising edge in the waveform. Using this waveform, the controller measures the amount of time between these rising edges. Using the measured amount of time between the rising edges, the controller proceeds to determine the frequency value corresponding to power provided by the input source. The controller proceeds to determine if the frequency value is within a range of values representative of the operational frequency limits the input source should be operating within. If the controller determines the frequency value is operating outside of this frequency range, the controller transmits a signal to a power conditioning module. The power conditioning module proceeds to compensate the input source to ensure the input source is operating within the frequency value range. In discussing FIG. 4, references may be made to the components in FIGS. 1-2B to provide contextual examples. In one implementation, the controller 114 as in FIG. 1 executes operations 402-414 to determine a frequency from a measured period of time. Although FIG. 4 is described as implemented by the controller, it may be executed on other suitable components. For example, FIG. 4 may be implemented in the form of executable instructions on a machine-readable storage medium 504 and 604 as in FIGS. 5-6.

At operations 402-408, the controller obtains the waveform from the comparator circuit. The waveform includes a voltage signal produced by the comparator circuit based on a comparison between a voltage signal by the input source and a known voltage. When the input source has a voltage higher than the known voltage, this creates the rising edges for detection. The detected rising edges are used to measure the amount of time between these rising edges. The amount of time is used to determine the frequency value for verification at operation 410. Operations 402-408 may be similar in functionality to operations 302-312 as in FIG. 3.

At operation 410, the controller uses the frequency value determined at operation 408. The frequency value is used to determine whether the frequency of the input source within a range of values. The range of values represents the frequency operational or specification limits which place parameters on a range of values in how the input source should be operating. If it is determined the frequency value is within the range of values, the controller may continue detecting the rising edges in the waveform as at operation 412. If it is determined the frequency value is outside of the range of values, the controller transmits a signal to a power conversion module as at operation 414.

At operation 412, if the controller determines the frequency value is within the range of values, the controller does not activate the power conditioning module. If the frequency value is within the range of values, this indicates the input source is operating within the operational or specification limits. As such, the power system may be operating in an indefectible manner. In one implementation, upon determining the frequency value is within the range of values, the controller may signal for operation of a power conversion module. The power conversion module may convert the power from the input source 102 to an amount of power for consumption by the load.

At operation 414, if the controller determines the frequency value is outside of the range of values, the controller transmits the signal to the power conditioning module. The frequency value is considered the frequency of oscillations of AC in the electrical power transmitted from the input source. If the frequency value is determined to be outside of the range of values, this indicates the input power source may be supplying power at a particular value that may cause the power system to operate in a sub-optimal manner. As such, tracking the frequency value, the controller may compensate or remedy the frequency value through operation of the power conditioning module. The signal to the power conditioning module may specify how to remedy the frequency value so the value is brought within the range of values. In this example, the signal may include how to correct the power from the input source, such as compensating the frequency value to obtain a higher frequency value or a lower frequency value.

Referring now to FIGS. 5 and 6, block diagrams of example computing devices are illustrated in accordance with the present disclosure. The example computing devices 500 and 600 include a processing resource 502 and 602 in which to execute various instructions 506-510 and 602-622 in each figure. Accordingly, while the instructions are illustrated in a particular order, implementations are not intended to be so limited. Rather, it is contemplated each instruction may occur simultaneously and/or in conjunction with other instructions.

FIG. 5 is a block diagram of computing device 500 with a processing resource 502 to execute instructions 506-510 within a machine-readable storage medium 504. Specifically, the computing device 500 with the processing resource 502 is to determine an AC characteristic from a measured period of time. The period of time is measured from a set of rising edges in a waveform. Although the computing device 500 includes processing resource 502 and machine-readable storage medium 504, it may also include other components that would be suitable to one skilled in the art. For example, the computing device 500 may include the controller 114 as in FIG. 1. The computing device 500 is an electronic device with the processing resource 502 capable of executing instructions 506-510, and as such embodiments of the computing device 500 include a mobile device, client device, personal computer, desktop computer, laptop, tablet, video game console, or other type of electronic device capable of executing instructions 506-510. The instructions 506-510 may be implemented as methods, functions, operations, and other processes implemented as machine-readable instructions stored on the storage medium 504, which may be non-transitory, such as hardware storage devices (e.g., random access memory (RAM), read only memory (ROM), erasable programmable ROM, electrically erasable ROM, hard drives, and flash memory).

The processing resource 502 may fetch, decode, and execute instructions 506-510 to determine an AC characteristic of an input source based on a measured period of time in a waveform. Specifically, the processing resource 502 executes instructions 506-510 to: obtain a waveform representative of voltage from an input source; measure a period of time between rising edges in the waveform; and determine one of the alternating characteristics of the input source based on the measured period of time in the waveform.

The machine-readable storage medium 504 includes instructions 506-510 for the processing resource 502 to fetch, decode, and execute. In another embodiment, the machine-readable storage medium 504 may be an electronic, magnetic, optical, memory, storage, flash-drive, or other physical device that contains or stores executable instructions. Thus, the machine-readable storage medium 504 may include, for example, Random Access Memory (RAM), an Electrically Erasable Programmable Read-Only Memory (EEPROM), a storage drive, a memory cache, network storage, a Compact Disc Read Only Memory (CDROM) and the like. As such, the machine-readable storage medium 504 may include an application and/or firmware which can be utilized independently and/or in conjunction with the processing resource 502 to fetch, decode, and/or execute instructions of the machine-readable storage medium 504. The application and/or firmware may be stored on the machine-readable storage medium 504 and/or stored on another location of the computing device 500.

FIG. 6 is a block diagram of computing device 600 with a processing resource 602 to execute instructions 606-622 within a machine-readable storage medium 604. Specifically, the computing device 600 with the processing resource 602 is to determine an AC characteristic value from a measured period of time. The period of time is measured from a set of rising edges or between a rising edge and falling edge in a waveform. Based on the determined characteristic value, the processing resource 602 verifies if the characteristic is within a set of values and then makes an appropriate response. Although the computing device 600 includes processing resource 602 and machine-readable storage medium 604, it may also include other components that would be suitable to one skilled in the art. For example, the computing device 600 may include the controller 114 as in FIG. 1. The computing device 600 is an electronic device with the processing resource 602 capable of executing instructions 606-622, and as such embodiments of the computing device 600 include a mobile device, client device, personal computer, desktop computer, laptop, tablet, video game console, or other type of electronic device capable of executing instructions 606-622. The instructions 606-622 may be implemented as methods, functions, operations, and other processes implemented as machine-readable instructions stored on the storage medium 604, which may be non-transitory, such as hardware storage devices (e.g., random access memory (RAM), read only memory (ROM), erasable programmable ROM, electrically erasable ROM, hard drives, and flash memory).

The processing resource 602 may fetch, decode, and execute instructions 606-622 to determine an AC characteristic of an input source and determine if the AC characteristic is within a range of values. If the AC characteristic is outside of the range of values, the processing resource 602 may transmit a signal to turn on a power conditioning module. Turning on the power conditioning module, enables the input source to obtain the AC characteristic within the range of values. Specifically, the processing resource 602 executes instructions 606-622 to: obtain a waveform from a comparator circuit; measure a period of time of the waveform by detecting a first and second rising edge and/or detecting a rising edge and falling edge; determine the AC characteristic of the input source based on the measured period of time; determine a frequency of the input source based on the measured period of time represented by the set of rising edges; determine an amplitude of the input source based on the measured period of time represented by the riding edge and the falling edge; determine if the AC characteristic is within a range of values; and upon the determination the AC characteristic is outside of the range of values, activate a power conditioning module.

The machine-readable storage medium 604 includes instructions 606-622 for the processing resource 602 to fetch, decode, and execute. In another embodiment, the machine-readable storage medium 604 may be an electronic, magnetic, optical, memory, storage, flash-drive, or other physical device that contains or stores executable instructions. Thus, the machine-readable storage medium 604 may include, for example, Random Access Memory (RAM), an Electrically Erasable Programmable Read-Only Memory (EEPROM), a storage drive, a memory cache, network storage, a Compact Disc Read Only Memory (CDROM) and the like. As such, the machine-readable storage medium 604 may include an application and/or firmware which can be utilized independently and/or in conjunction with the processing resource 602 to fetch, decode, and/or execute instructions of the machine-readable storage medium 604. The application and/or firmware may be stored on the machine-readable storage medium 604 and/or stored on another location of the computing device 600.

Although certain embodiments have been illustrated and described herein, it will be greatly appreciated by those of ordinary skill in the art that a wide variety of alternate and/or equivalent embodiments or implementations calculated to achieve the same purposes may be substituted for the embodiments shown and described without departing from the scope of this disclosure. Those with skill in the art will readily appreciate that embodiments may be implemented in a variety of ways. This application is intended to cover adaptions or variations of the embodiments discussed herein. Therefore, it is manifestly intended that embodiments be limited only by the claims and equivalents thereof.

We claim:

1. A system comprising:
a comparator circuit to generate a waveform of an input source; and
a controller to:
measure a period of time associated with the waveform; and
determine an alternating current (AC) characteristic of the input source based on the measured period of time.

2. The system of claim 1 wherein the AC characteristic of the input source includes at least one of a frequency of voltage and an amplitude of voltage supplied by the input source.

3. The system of claim 1 comprising:
a rectifying circuit to rectify alternating current (AC) from the input source prior to generation of the waveform by the comparator circuit.

4. The system of claim 1 comprising:
an optocoupler to provide isolation between the controller and the comparator circuit.

5. The system of claim 1 wherein to measure the period of time associated with the waveform, the controller is to:
obtain the waveform;
detect a first rising edge and a second rising edge on the waveform;
determine the period of time between the first rising edge and the second rising edge; and
determine the frequency based on the period of time.

6. The system of claim 1 wherein the controller is further to:
determine whether the AC characteristic is within a range of values based on the waveform.

7. The system of claim 1 wherein to generate the waveform of the input source, the comparator is to:
obtain a voltage corresponding to the input source; and
compare the voltage corresponding to the input source to a known voltage, wherein if the voltage corresponding to the input source is larger than the known voltage creates a rising edge in the waveform.

8. A non-transitory machine-readable storage medium comprising instructions that when executed by a processing resource cause a computing device to:
obtain a waveform of an input source from a comparator circuit;
measure a period of time associated with the waveform; and
determine an alternating current (AC) characteristic corresponding to the input source based on the period of time associated with the waveform.

9. The non-transitory machine-readable storage medium of claim 8 comprising instructions that when executed by the processing resource cause the computing device to:
determine if the AC characteristic is within a specified range; and
activate a power conditioning module if the AC characteristic is outside of the specified range.

10. The non-transitory machine-readable storage medium of claim 8 wherein the AC characteristic includes at least one of: frequency of voltage and an amplitude of voltage as supplied by the input source.

11. The non-transitory machine-readable storage medium of claim 8 wherein to measure the period of time associated with the waveform comprises instructions that when executed cause the computing device to:
detect a first rising edge of voltage corresponding to the waveform;
detect the second rising edge of voltage corresponding to the waveform;
measure the period of time between the first rising edge and the second rising edge; and
determine a frequency of voltage supplied by the input source based on the measured period of time.

12. The non-transitory machine-readable storage medium of claim 8 wherein to measure the period of time associated with the waveform comprises instructions that when executed cause the computing device to:
detect a falling edge of voltage corresponding to the waveform;
detect a rising edge of voltage corresponding to the waveform;
measure the period of time between the falling edge of voltage and the rising edge of voltage; and
determine an amplitude of voltage based on the measured period of time.

13. A method, executable by a controller, the method comprising:
obtaining a waveform as generated by a comparator circuit, the waveform representative of an input source;
detecting a first rising edge of the waveform;
detecting a second rising edge of the waveform, wherein the rising edges represent when the input source exceeds a known voltage at the comparator circuit;
measuring a period of time between the first rising edge and the second rising edge;
determining a frequency value based on the period of time.

14. The method of claim 13 comprising:
verifying the frequency is within a specified range of values;
if the frequency value is outside of the specified range of values, activating a power conditioning module to compensate the input source; and
if the frequency value is within the specified range of values, activating a power conversion module.

15. The method of claim 13 comprising:
measuring a different period of time between a falling edge and the second rising edge of the waveform;
determining an amplitude of the waveform based on the measured different period of time.
